(19) United States
(12) Patent Application Publication
(10) Pub. No.: US 2013/0307132 A1
(43) Pub. Date: Nov. 21, 2013

(54) SEMICONDUCTOR DEVICE

(71) Applicant: SUMITOMO ELECTRIC INDUSTRIES, LTD., Osaka-shi (JP)

(72) Inventor: Yoshisumi KAWABATA, Osaka-shi (JP)

(73) Assignee: Sumitomo Electric Industries, Ltd., Osaka-shi (JP)

(21) Appl. No.: 13/867,915

(22) Filed: Apr. 22, 2013

Related U.S. Application Data
(60) Provisional application No. 61/648,215, filed on May 17, 2012.

(30) Foreign Application Priority Data
May 17, 2012 (JP) 2012-112988

(51) Int. Cl. H01L 23/495

(52) U.S. Cl. CPC H01L 23/4952
USPC 257/676

(57) ABSTRACT

A semiconductor device includes at least one semiconductor chip and a lead. The lead has a first portion connected to the semiconductor chip via a wiring. The first portion of the lead extends along a first direction and is placed so as to face the semiconductor chip.

### CROSS-REFERENCE RELATED APPLICATIONS

This application claims priority to Provisional Application Ser. No. 61/648,215, filed on May 17, 2012 and claims the benefit of Japanese Patent Application No. 2012-112988, filed on May 17, 2012, all of which are incorporated herein by reference in their entirety.

### BACKGROUND

1. Field

The present invention relates to a semiconductor device.

2. Related Background

As examples of semiconductor devices, a case-shaped semiconductor device and a resin sealed semiconductor device are known (see Causes of Failures and Techniques for Improving and Evaluating Reliability of Wire Bonding Focused on Cu Wires, Technical Information Institute Co., Ltd., Jul. 29, 2011, p. 163 and p. 263). In the resin sealed semiconductor device, a semiconductor chip mounted on a die pad is connected to a lead via a wire.

### SUMMARY

However, in the above-stated semiconductor device, the semiconductor chip is distanced from the lead, and so the wire becomes longer. As the wire becomes longer, a heat dissipation property of the wire is lowered, so that a fusing current is decreased. As a result, it becomes impossible to pass a large current through the wire.

It is an object of the present invention to provide a semiconductor device having a shortened wiring between a semiconductor chip and a lead.

The semiconductor device according to one aspect of the present invention includes: at least one semiconductor chip; and a lead having a first portion connected to the at least one semiconductor chip via a wiring, wherein the first portion of the lead extends along a first direction and is placed so as to face the at least one semiconductor chip.

In this semiconductor device, the semiconductor chip and the first portion of the lead are placed so as to face each other, so that a wiring between the semiconductor chip and the lead is shortened.

The above-stated semiconductor device may further include a die pad having a chip mounting surface for mounting the at least one semiconductor chip.

The at least one semiconductor chip may include a plurality of semiconductor chips, and a plurality of the semiconductor chips may be arrayed along the first direction. In this case, even when the number of semiconductor chips is increased, wirings between the semiconductor chips and the lead do not cross each other.

A surface of the first portion of the lead may be placed on a same plane as a surface of the at least one semiconductor chip. In this case, a wiring between the semiconductor chip and the lead is further shortened.

A material of the at least one semiconductor chip may include a wide-band gap semiconductor. In this case, it becomes possible to pass a large current through the wiring compared with the case of a semiconductor chip made of silicon.

The lead may have a second portion connected to the first portion, the second portion extending along the first direction, and the first portion may protrude more than the second portion toward the at least one semiconductor chip in a second direction intersecting with the first direction. In this case, a distance between the semiconductor chip and the lead is shortened, and the wiring is further shortened thereby.

The semiconductor device may further include a resin portion covering the at least one semiconductor chip and the first portion of the lead. As a consequence, the semiconductor chip and the lead may be fixed onto the resin portion.

As mentioned above, a semiconductor device having a shortened wiring between a semiconductor chip and a lead may be provided.

### BRIEF DESCRIPTION OF THE DRAWINGS

FIG. 1 is a plan view schematically showing a semiconductor device according to a first embodiment;

FIG. 2 is a cross sectional view showing the semiconductor device taken along a line II-II of FIG. 1;

FIG. 3 is a cross sectional view showing the semiconductor device taken along a line of FIG. 1;

FIG. 4 is a plan view schematically showing a semiconductor device according to a second embodiment;

FIG. 5 is a cross sectional view showing the semiconductor device taken along a line V-V of FIG. 4;

FIG. 6 is a cross sectional view showing the semiconductor device taken along a line VI-VI of FIG. 4;

FIG. 7 is a plan view schematically showing a semiconductor device according to a third embodiment;

FIG. 8 is a plan view schematically showing a semiconductor device according to a fourth embodiment; and

FIG. 9 is a plan view schematically showing a semiconductor device according to a fifth embodiment.

### DETAILED DESCRIPTION

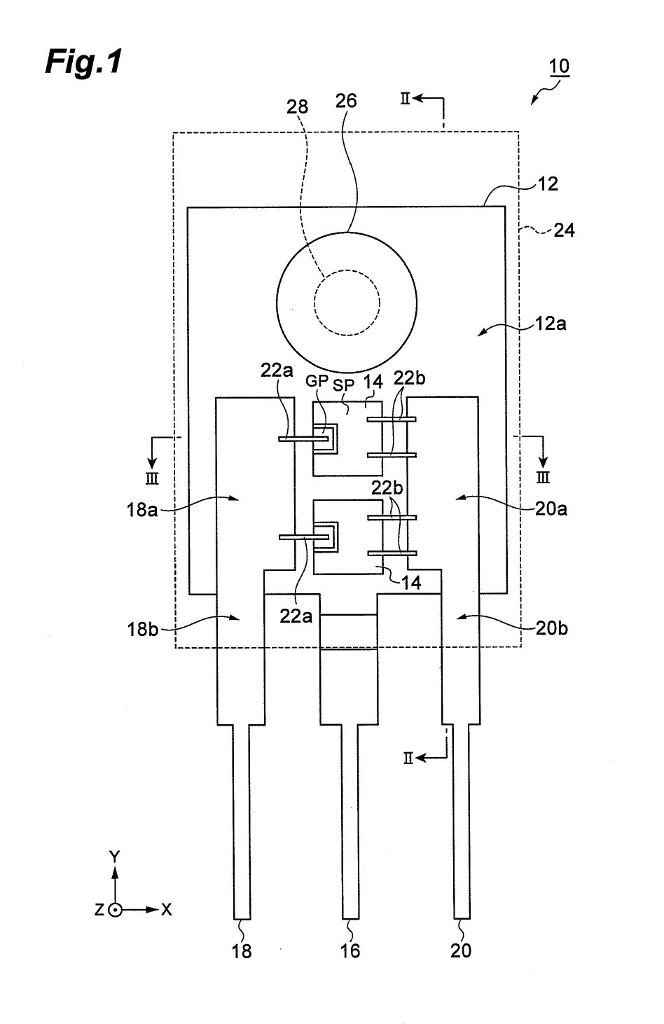

Hereinbelow, the embodiments of the present invention will be described in detail with reference to the accompanying drawings. In a description of the drawings, the same or like component members are designated by the same reference numerals to omit redundant explanation. In FIGS. 1 to 9, an XYZ orthogonal coordinate system is shown.

### First Embodiment

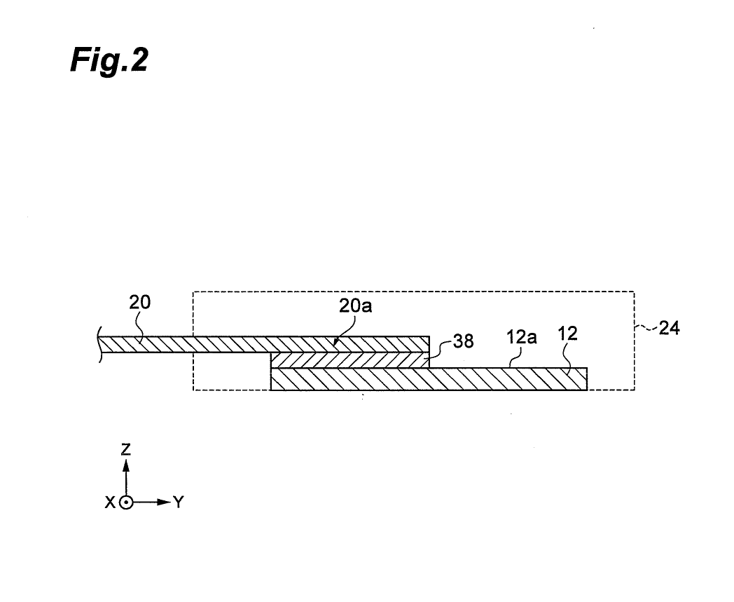

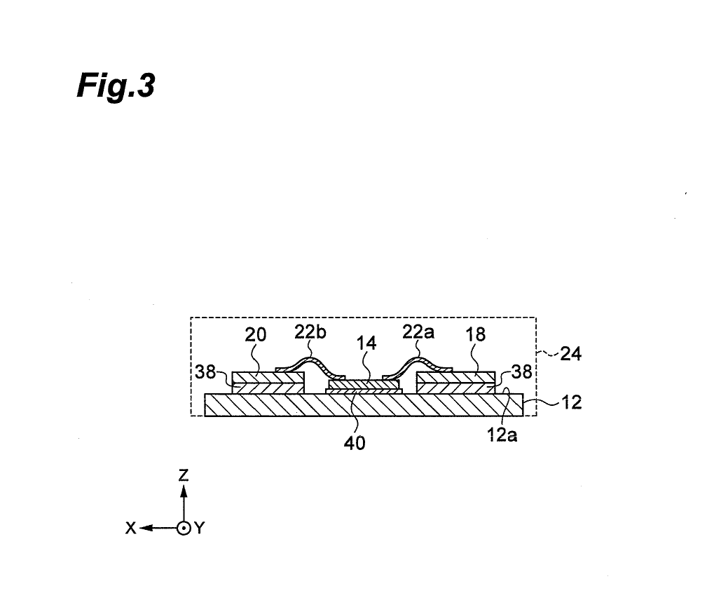

FIG. 1 is a plan view schematically showing a semiconductor device according to the first embodiment. FIG. 2 is a cross sectional view showing the semiconductor device taken along a line II-II of FIG. 1. FIG. 3 is a cross sectional view showing the semiconductor device taken along a line of FIG. 1. A semiconductor device 10 shown in FIGS. 1 to 3 is a resin sealed semiconductor device. The semiconductor device 10 includes a plurality of semiconductor chips 14 and a first lead 18.

The semiconductor device 10 may include a die pad 12 having a chip mounting surface 12a for mounting the semiconductor chip 14. The die pad 12 may electrically be connected to the semiconductor chip 14. For example, the die pad 12 is in a plate shape. For example, the chip mounting surface 12a is rectangular. Examples of the material of the die pad 12 include metal such as copper (Cu) and copper alloys. The die pad 12 may have a through hole 26 formed to penetrate the die pad 12 in a board thickness direction. The through hole 26 is a hole for passing a screw which is used, for example, to screw the semiconductor device 10 to another member (such as a heat sink).

The semiconductor device 10 may include a second lead 16 and a third lead 20. The leads 16, 18, and 20 extend along a direction Y (first direction), and are arrayed along a direction X (second direction that intersects with the first direction). The lead 16 is positioned between the leads 18 and 20. The leads 16, 18, 20 and the die pad 12 may constitute a lead frame. The semiconductor device 10 is a power semiconductor device for use in, for example, a power source or the like. Examples of the package form of the semiconductor device 10 include a general TO series. Examples of the TO series include TO-247, TO-220, TO-263 (D2-PAK), and TO-252 (D-PAK).

The lead 18 has a first portion 18a connected to the semiconductor chip 14 via a wiring 22a. The first portion 18a extends along the direction Y and is placed so as to face the semiconductor chip 14. The first portion 18a is placed so as to face a side along the direction Y of the semiconductor chip 14. The lead 18 may have a second portion 18b connected to the first portion 18a. The second portion 18b extends along the direction Y. The first portion 18a may be larger in width than the second portion 18b. The first portion 18a may protrude more than the second portion 18b toward the semiconductor chip 14 in the direction X.

The lead 20 has a first portion 20a connected to the semiconductor chip 14 via a plurality of the wirings 22b. The semiconductor chip 14 may be connected to the first portion 20a via a single wiring 22b. The first portion 20a extends along the direction Y and is placed so as to face the semiconductor chip 14. The first portion 20a is placed so as to face a side along the direction Y of the semiconductor chip 14. The lead 20 may have a second portion 20b connected to the first portion 20a. The second portion 20b extends along the direction Y. The first portion 20a may be larger in width than the second portion 20b. The first portion 20a may protrude more than the second portion 20b toward the semiconductor chip 14 in the direction X.

The first portion 18a of the lead 18 is placed so as to face the first portion 20a of the lead 20. The semiconductor chip 14 is placed between the first portion 18a of the lead 18 and the first portion 20a of the lead 20. The semiconductor chips 14 may be arrayed along the direction Y. The second portion 18b of the lead 18 may be placed so as to face the second portion 20b of the lead 20. The wirings 22a and 22b may extend along the direction X.

The semiconductor chip 14 is mounted at a specified position on the chip mounting surface 12a. Examples of the semiconductor chip 14 include transistors such as a MOS-FET and an insulated gate bipolar transistor (IGBT), and diodes such as a PN junction diode and a Schottky barrier diode. The semiconductor chip 14 may be mounted on the chip mounting surface 12a via an adhesive layer 40 made of metal solder containing lead, metal solder containing no lead, or a material including conductive resin or the like. Examples of the material of the semiconductor chip 14 include a wide-band gap semiconductor, and silicon and other semiconductors. The wide-band gap semiconductor has a band gap larger than a silicon band gap. Examples of the wide-band gap semiconductor include silicon carbide (SiC), gallium nitride (GaN), and diamond.

The semiconductor chip 14 may have electrode pads GP and SP. The electrode pad GP is connected to the lead 18 via a wiring 22a. The electrode pad SP is connected to the lead 20 via a wiring 22b. When the semiconductor chip 14 includes a MOS-FET, the electrode pad GP corresponds to a gate electrode pad, and the electrode pad SP corresponds to a source electrode pad. When the semiconductor chip 14 includes an IGBT, the electrode pad GP corresponds to a gate electrode pad, and the electrode pad SP corresponds to an emitter electrode pad. An additional electrode pad, that is, a drain electrode pad or a collector electrode pad for example, may be formed on the entire back surface of the semiconductor chip 14.

The semiconductor device 10 may include an insulating member 38 placed between the die pad 12 and the leads 18 and 20. The insulating member 38 is interposed between the die pad 12 and the first portion 18a of the lead 18 and the first portion 20a of the lead 20 in a direction Z (third direction that intersects with the first direction and the second direction). The insulating member 38 is, for example, an insulating substrate or an insulating layer. Examples of the material of the insulating member 38 include resin such as epoxy resin or ceramics. The die pad 12, the insulating member 38, and the leads 18 and 20 may be connected to each other with an adhesive.

An inner end of the lead 16 is mechanically and integrally joined with the die pad 12. Since the die pad 12 has conductivity, the lead 16 and the die pad 12 are electrically connected. Examples of the material of the lead 16 include the same materials as those of the die pad 12.

When the semiconductor chip 14 includes a MOS-FET, the lead 16 corresponds to a drain electrode terminal, the lead 18 corresponds to a gate electrode terminal, and the lead 20 corresponds to a source electrode terminal. When the semiconductor chip 14 includes an IGBT, the lead 16 corresponds to a collector electrode terminal, the lead 18 corresponds to a gate electrode terminal, and the lead 20 corresponds to an emitter electrode terminal. Examples of the material of the leads 18 and 20 include metal such as copper and copper alloy. The wirings 22a and 22b may be a wire or a bonding ribbon. Examples of the material of the wirings 22a and 22b include metal such as aluminum, gold, and copper. The wirings 22a and 22b are connected to the leads 18 and 20 and the semiconductor chip 14 by wire bonding with use of, for example, supersonic waves or pressurization.

The die pad 12, the semiconductor chip 14, the first portion 18a of the lead 18, and the first portion 20a of the lead 20 may be covered with a resin portion 24. The inner ends of the leads 16, 18, and 20 are inserted into the resin portion 24. The portions of the leads 16, 18, and 20 which are inside the resin portion 24 are so-called inner lead portions. The portions of the leads 16, 18, and 20 which are outside the resin portion 24 are so-called outer lead portions. In one example, the resin portion 24 has an outer shape of generally a rectangular parallelepiped. Examples of the material of the resin portion 24 include thermoplastic resin such as polyphenylene sulfide resin (PPS resin) and a liquid crystal polymer. The resin portion 24 may be formed by molding the die pad 12 and the semiconductor chip 14 with thermoplastic resin. The resin portion 24 has a through hole 28 formed therein, with a central axis line of the through hole 26 of the die pad 12 being used as a central axis line of the through hole 28. Like the through hole 26, the through hole 28 is a hole for passing a screw at the time of screwing or the like. The through hole 28 is smaller in diameter than the through hole 26.

In the semiconductor device 10, the semiconductor chip 14 and the first portion 18a of the lead 18 are placed so as to face each other, which shortens the wiring 22a between the semiconductor chip 14 and the lead 18. Similarly, the semiconductor chip 14 and the first portion 20a of the lead 20 are placed so as to face each other, which shortens the wiring 22b between the semiconductor chip 14 and the lead 20. When the length of the wirings 22a and 22b is shortened, the heat dissipation property of the wirings 22a and 22b is enhanced, so that a fusing current is increased. Therefore, even when a large current passes, the wirings 22a and 22b are less likely to be disconnected. Accordingly, it becomes possible to pass a large current even with a small number of the wirings 22a and 22b, and therefore manufacturing costs of the semiconductor device 10 can be lowered.

Table 1 shows a relation between a planar distance of a wiring and a fusing current value in examples. The planar distance of the wiring corresponds to a length of a wiring when the wiring is projected onto a plane. “Gel present” corresponds to the case where the wiring is covered with gel. “Gel not present” corresponds to the case where the wiring is not covered with gel.

TABLE 1

| | | | |
|---|---|---|---|
| Planar distance of the wiring (mm) | 4 | 5 | 6 |

| | | | | |
|---|---|---|---|---|
| Fusing current value | Gel not present | 16.5 | 14.5 | 12.5 |
| (A) | Gel present | 17 | 15 | 13.5 |

As shown in Table 1, as the wiring becomes longer, the fusing current tends to gradually decrease.

Further, when the length of the first portion 18a of the lead 18 is increased, the wirings 22a, if increased in number, are less likely to be clustered in the first portion 18a of the lead 18. When the length of the first portion 20a of the lead 20 is increased, the wirings 22b, if increased in number, are less likely to be clustered in the first portion 20a of the lead 20. This makes it possible to lower the possibility that the wirings 22a and 22b come into contact with each other. Increasing the number of the wirings 22a and 22b makes it possible to pass a larger current. Furthermore, it also becomes possible to suppress reduction in manufacturing yields of the semiconductor device 10 due to bonding error and adhesion failure.

When the material of the semiconductor chip 14 includes a wide-band gap semiconductor, it becomes possible to pass a larger current through the wirings 22a and 22b compared with the case of the semiconductor chip 14 made of silicon. Accordingly, such effects as avoiding contact between wirings and achieving shortened wirings become notable.

When the semiconductor device 10 includes the insulating member 38, the leads 18 and 20 are insulated from the die pad 12 by the insulating member 38. The leads 18 and 20 may be supported by the die pad 12 through the insulating member 38. As a result, the configuration of the semiconductor device 10 is stabilized.

Generally, a plurality of semiconductor chips are connected to a gate lead and a source lead via wires. In this case, a wiring between one semiconductor chip and the source lead may possibly cross a wiring between another semiconductor chip and the gate lead. Contrary to this, when a plurality of the semiconductor chips 14 are arrayed along the direction Y in the semiconductor device 10, the wirings 22a and 22b between the semiconductor chip 14 and the leads 18 and 20 do not cross each other even with the number of the semiconductor chips 14 being increased.

When the wirings 22a and 22b extend along the direction X, the wiring 22a and the wiring 22b are most separated from each other. As a result, the possibility that the wiring 22a and the wiring 22b come into contact with each other can further be reduced. The length of the wirings 22a and 22b can be minimized.

When the first portion 18a of the lead 18 protrudes more than the second portion 18b toward the semiconductor chip 14 in the direction X, a distance between the semiconductor chip 14 and the lead 18 is shortened, so that the wiring 22a is further shortened. Similarly, when the first portion 20a of the lead 20 protrudes more than second portion 20b toward the semiconductor chip 14 in the direction X, a distance between the semiconductor chip 14 and the lead 20 is shortened, so that the wiring 22b is further shortened.

When the semiconductor chip 14, the first portion 18a of the lead 18, and the first portion 20a of the lead 20 are covered with the resin portion 24, the semiconductor chip 14 and the leads 18 and 20 may be fixed to the resin portion 24.

### Second Embodiment

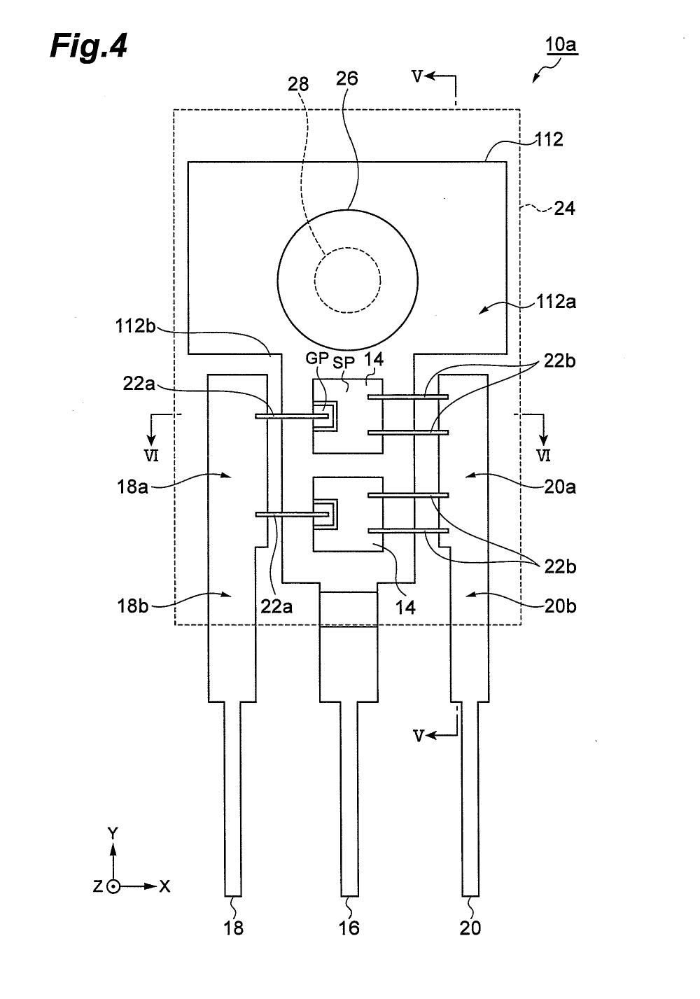

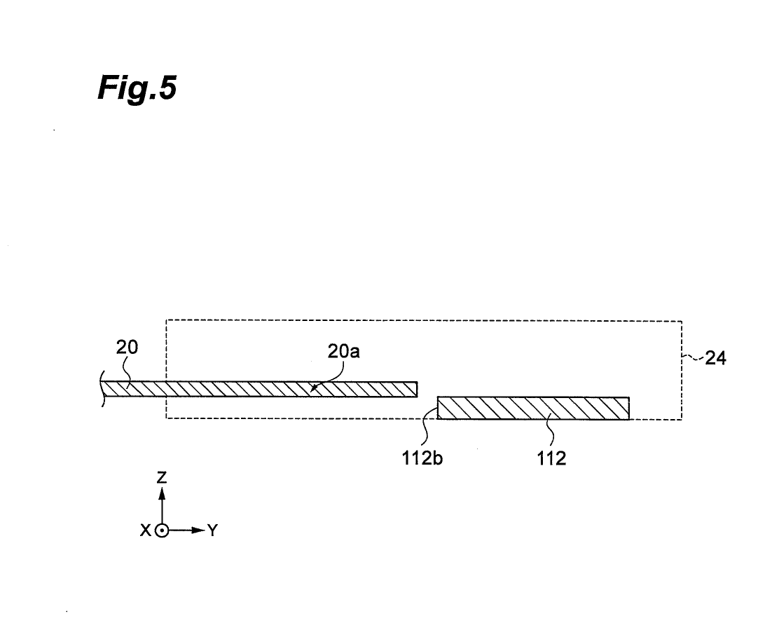

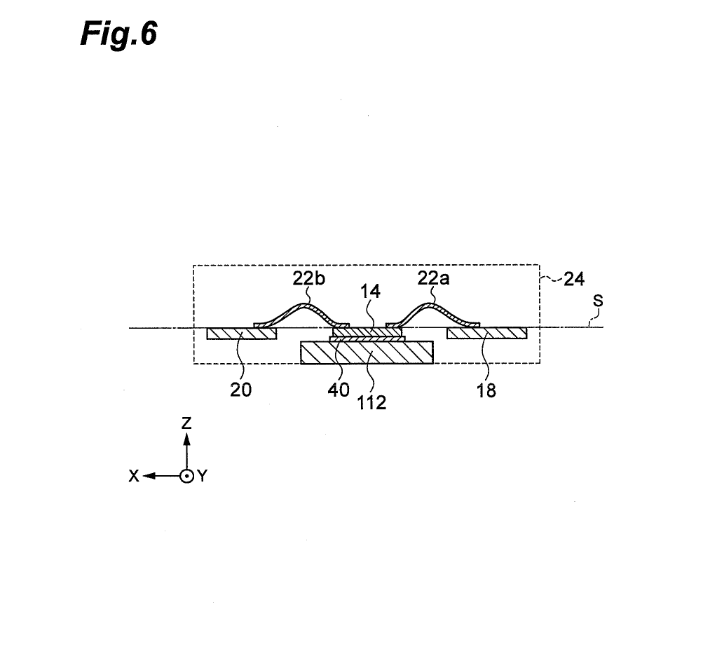

FIG. 4 is a plan view schematically showing a semiconductor device according to the second embodiment. FIG. 5 is a cross sectional view showing the semiconductor device taken along a line V-V of FIG. 4. FIG. 6 is a cross sectional view showing the semiconductor device taken along a line VI-VI of FIG. 4. A semiconductor device 10a shown in FIGS. 4 to 6 has the same configuration as the semiconductor device 10 except that a die pad 112 is included in place of the die pad 12 and that the insulating member 38 is not included.

The die pad 112 has a chip mounting surface 112a for mounting the semiconductor chip 14. The die pad 112 has a notch portion 112b corresponding to shapes of the first portion 18a of the lead 18 and the first portion 20a of the lead 20. A clearance is formed between the notch portion 112b and the first portion 18a of the lead 18 and the first portion 20a of the lead 20. Surfaces of the first portion 18a of the lead 18 and the first portion 20a of the lead 20 are placed on a same plane S as the surface of the semiconductor chip 14.

In the semiconductor device 10a, the same operational effects as those of the semiconductor device 10 can be obtained. Further, in the semiconductor device 10a, the surfaces of the first portion 18a of the lead 18 and the first portion 20a of the lead 20 are placed on the same plane S as the surface of the semiconductor chip 14. As a result, compared with the case where the surfaces of the leads 18 and 20 are placed on a different plane from the surface of the semiconductor chip 14, the wiring 22a between the semiconductor chip 14 and the lead 18 and the wiring 22b between the semiconductor chip 14 and the lead 20 are shortened.

### Third Embodiment

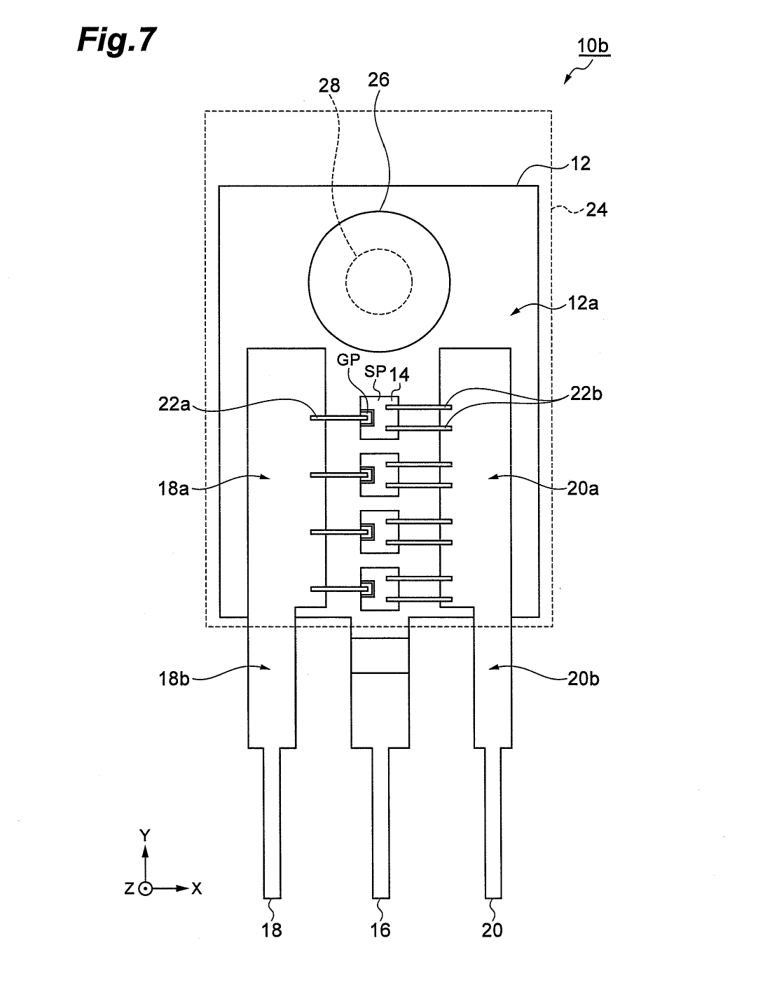

FIG. 7 is a plan view schematically showing a semiconductor device according to the third embodiment. A semiconductor device 10b shown in FIG. 7 has the same configuration as the semiconductor device 10 except that the number of the semiconductor chips 14 is larger. A plurality of the semiconductor chips 14 are arrayed along an extending direction of the first portion 18a of the lead 18 and the first portion 20a of the lead 20. In the semiconductor device 10b, the same operational effects as those of the semiconductor device 10 can be obtained. Further, by increasing the length of the first portion 18a of the lead 18 and the first portion 20a of the lead 20, the number of the semiconductor chips 14 can be increased.

### Fourth Embodiment

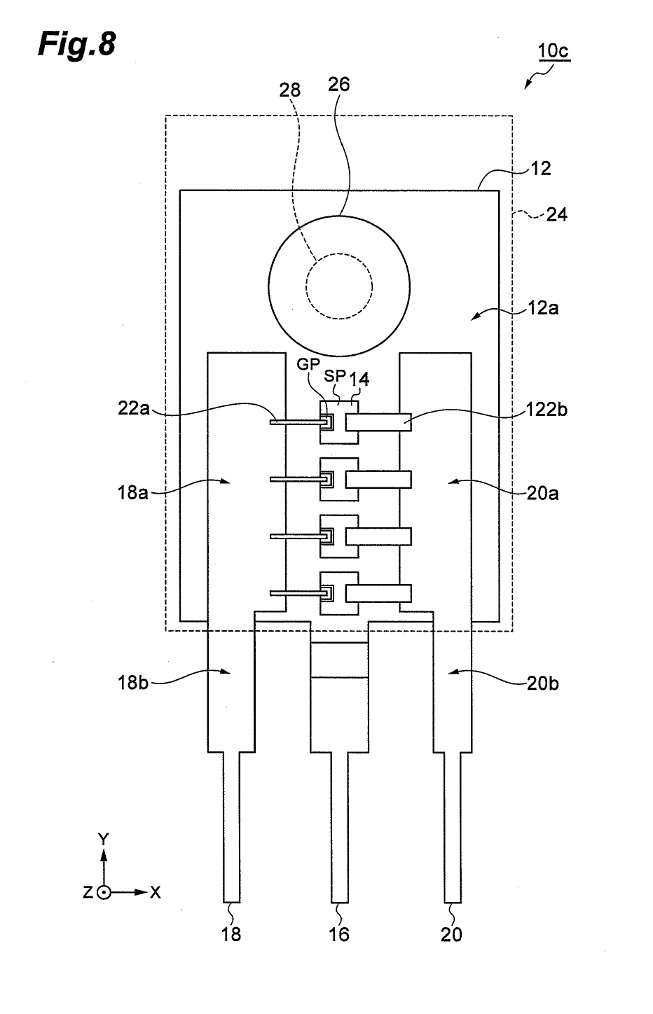

FIG. 8 is a plan view schematically showing a semiconductor device according to the fourth embodiment. A semiconductor device 10c shown in FIG. 8 has the same configuration as the semiconductor device 10b except that a wiring 122b is included in place of the wiring 22b. The wiring 122b is a bonding ribbon. In the semiconductor device 10c, the same operational effects as those of the semiconductor device 10b can be obtained.

### Fifth Embodiment

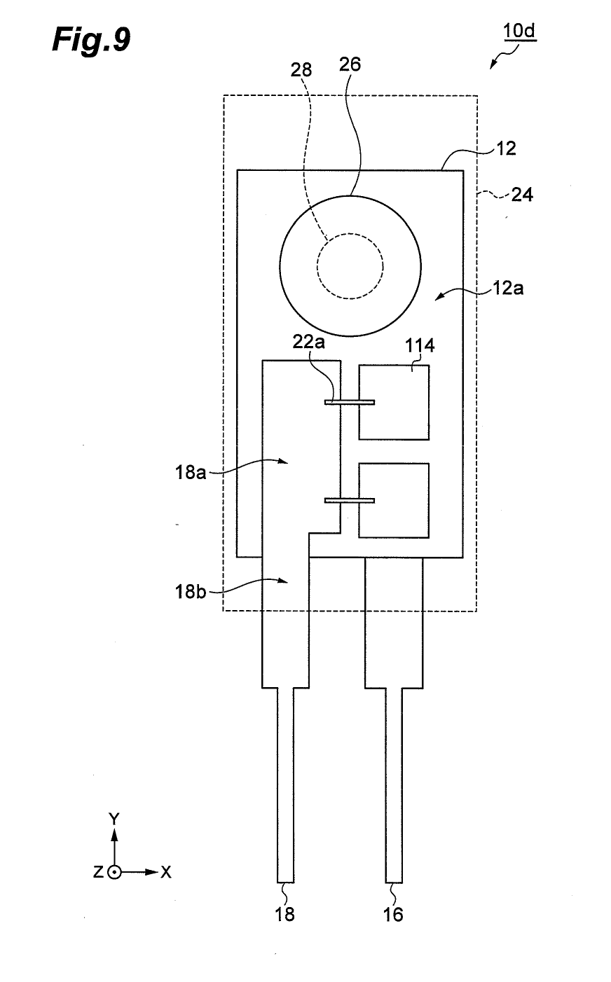

FIG. 9 is a plan view schematically showing a semiconductor device according to the fifth embodiment. A semiconductor device 10d shown in FIG. 9 has the same configuration as the semiconductor device 10 except that a semiconductor chip 114 is included in place of the semiconductor chip 14 and that the lead 20 and the wiring 22b are not included. The semiconductor chip 114 is a diode. The semiconductor chip 114 has a surface electrode and a back-surface electrode. The surface electrode of the semiconductor chip 114 is connected to the lead 18 via a wiring 22a. The back-surface electrode of the semiconductor chip 114 is connected to the lead 16 via a die pad 12. In the semiconductor device 10d, the same operational effects as those of the semiconductor device 10 can be obtained.

Although preferred embodiments of the present invention have been described in detail in the foregoing, the present invention is not limited to the embodiments disclosed.

For example, the semiconductor devices 10, 10a to 10d may also include one or more semiconductor chips 14, one or more semiconductor chips 114, one or more wirings 22a, one or more wirings 22b, and one or more wirings 122b.

The semiconductor chip 14 may include a horizontal type transistor in place of a vertical type transistor. In this case, an electrode pad is not formed on the back surface of the semiconductor chip 14, but an additional electrode pad, that is, a drain electrode pad, a collector electrode pad or the like for example, is formed on the surface of the semiconductor chip 14. Accordingly, the semiconductor devices 10, 10a to 10c do not need to include the die pad 12. The semiconductor chip 14 is connected to the lead 16 via a wiring.

What is claimed is:

1. A semiconductor device, comprising:
at least one semiconductor chip; and
a lead having a first portion connected to the at least one semiconductor chip via a wiring, wherein
the first portion of the lead extends along a first direction and is placed so as to face the at least one semiconductor chip.

2. The semiconductor device according to claim 1, further comprising
a die pad having a chip mounting surface for mounting the at least one semiconductor chip.

3. The semiconductor device according to claim 1, wherein
the at least one semiconductor chip comprises a plurality of semiconductor chips, and
a plurality of the semiconductor chips are arrayed along the first direction.

4. The semiconductor device according to claim 1, wherein
a surface of the first portion of the lead is placed on a same plane as a surface of the at least one semiconductor chip.

5. The semiconductor device according to claim 1, wherein
a material of the at least one semiconductor chip includes a wide-band gap semiconductor.

6. The semiconductor device according to claim 1, wherein
the lead has a second portion connected to the first portion, the second portion extending along the first direction, and
the first portion protrudes more than the second portion toward the at least one semiconductor chip in a second direction intersecting with the first direction.

7. The semiconductor device according to claim 1, further comprising
a resin portion covering the at least one semiconductor chip and the first portion of the lead.
